(19) United States
(12) Patent Application Publication
(10) Pub. No.: US 2012/0055901 A1
(43) Pub. Date: Mar. 8, 2012

(54) SUBSTRATE FABRICATING APPARATUS AND SUBSTRATE FABRICATING METHOD

(75) Inventors: Chang Bo Lee, Busan (KR); Cheol Ho Choi, Gyunggi-do (KR); Dae Jo Hong, Gyunggi-do (KR)

(73) Assignee: SAMSUNG ELECTRO-MECHANICS CO., LTD., Gyunggi-do (KR)

(21) Appl. No.: 12/987,812

(22) Filed: Jan. 10, 2011

(30) Foreign Application Priority Data
Sep. 2, 2010 (KR) 1020100086024

(51) Int. Cl. H01L 21/306

(52) U.S. Cl. 216/13; 156/345.18

(57) ABSTRACT

Disclosed herein are a substrate fabricating apparatus and a substrate fabricating method. The substrate fabricating apparatus includes: a first injector that injects a first etchant to a circuit layer formed as an outermost layer of a base substrate to form first type of ruggedness; and a second injector that injects a second etchant to the circuit layer formed with the first type of ruggedness to form second type of ruggedness. The present invention provides the substrate fabricating apparatus and the substrate fabricating method that inject different etchants to the circuit layer to form different ruggedness, thereby making it possible to widen the specific surface area of the circuit layer to improve adhesion between the circuit layer and the protective layer.

### CROSS REFERENCE TO RELATED APPLICATION

This application claims the benefit of Korean Patent Application No. 10-2010-0086024, filed on Sep. 2, 2010, entitled “Substrate Fabricating Apparatus And Substrate Fabricating Method,” which is hereby incorporated by reference in its entirety into this application.

### BACKGROUND OF THE INVENTION

1. Technical Field

The present invention relates to a substrate fabricating apparatus and a substrate fabricating method.

2. Description of the Related Art

Generally, a printed circuit board (PCB) serves to conveniently connect various electronic components according to a predetermined scheme and is a part widely used for all electronic products from home appliances such as a digital TV, etc., to advanced communication devices, and is classified into a general purpose printed circuit board, a module type printed circuit board, a package type printed circuit board, etc.

Recently, a demand for a technology of directly mounting semiconductors chip on a printed circuit board has increased in order to meet the increased density of a semiconductor chip and the increased signal transfer speed. As a result, a development for high-density and high-reliability printed circuit board has been required in order to meet the increased integration of the semiconductor chip. A need exists for a technology for a printed circuit board capable of forming fine circuit patterns and micro via holes in order to meet these specifications and research into an apparatus for automatically fabricating a printed circuit board has been conducted in order to improve the fabricating productivity of a printed circuit board.

Generally, the printed circuit board includes a plurality of insulating layers and a plurality of circuit layers and the outermost layer thereof is provided with a solder resist layer in order to protect the insulating layers and the circuit layers. In this case, the quality and reliability of products depend on the adhesion between the circuit layer and the solder resist layer, which are the outermost layers, of the printed circuit board. In order to secure adhesion between the circuit layers and the solder resist layers, which are the outermost layers, it is preferable to widen a bonding area between the circuit layer and the solder resist layer as the outermost layers by widening a specific surface area of the circuit layer as the outermost layer.

In order to widen the specific surface area of the circuit layer as the outermost layer, the substrate fabricating method according to the prior art injects an etchant or plasma etching gas to the circuit layer as the outermost layer to etch the surface of the circuit layer as the outermost layer, such that the surface of the circuit layer as the outermost layer is rugged, thereby widening the specific surface area. In addition, research into a new etchant has been intensively conducted in order to widen the specific surface area of the circuit layer as the outermost layer.

However, the substrate fabricating method according to a prior art uses only one etchant by one injector to form only one type of ruggedness on the circuit layer as the outermost layer of the printed circuit board, such that there is a limit in widening the specific surface area of the circuit layer as the outermost layer. Therefore, adhesion between the solder resist layer and the circuit layer, which are the outermost layer, of the printed circuit board is relatively weak, thereby degrading the entire reliability of a product.

### SUMMARY OF THE INVENTION

The present invention has been made in an effort to provide a substrate fabricating apparatus and a substrate fabricating method having an advantage of improved adhesion between a solder resist layer and a circuit layer, which are the outermost layer, by forming different types of ruggedness on the circuit layer, which is the outermost layer of the printed circuit board.

A substrate fabricating apparatus according to a preferred embodiment of the present invention includes: a first injector that injects a first etchant to a circuit layer, which is formed as an outermost layer of a base substrate, to form first type of ruggedness; and a second injector that injects a second etchant to the circuit layer formed with the first type of ruggedness to form second type of ruggedness.

The substrate fabricating apparatus may further include a moving member moving the base substrate from the first injector to the second injector.

The substrate fabricating apparatus may further include: a loading part loading the base substrate into the first injector; and an unloading part carrying out the base substrate from the second injector to the outside.

The first injector and the second injector may be disposed on both surfaces of the base substrate.

The first etchant and the second etchant may be different from each other.

Any one of the first type of ruggedness and the second type of ruggedness may be higher than the other one.

The first etchant may be CuCl₂ or FeCl₂ and the second etchant may be HCOOH.

The first etchant, the second etchant, or both the first etchant and the second etchant may include organic acid.

A substrate fabricating method according to another preferred embodiment of the present invention includes: preparing a base substrate of which the outermost layer is formed with a circuit layer; forming first type of ruggedness by injecting a first etchant to the circuit layer; and forming second type of ruggedness by injecting a second etchant to the circuit layer formed with the first type of ruggedness.

The first etchant and the second etchant may be injected to the circuit layer formed as the outermost layer on both surfaces of the base substrate.

The first etchant and the second etchant may be different from each other.

Any one of the first type of ruggedness and the second type of ruggedness may be higher ruggedness than the other one.

The first etchant may be CuCl₂ or FeCl₂ and the second etchant may be HCOOH.

The first etchant, the second etchant, or both the first etchant and the second etchant may include organic acid.

The substrate fabricating method may further include after the forming the second type of ruggedness, forming a protective layer on the base substrate formed with the circuit layer.

The protective layer may be a solder resist layer.

### BRIEF DESCRIPTION OF THE DRAWINGS

FIG. 1 is a cross-sectional view of a substrate fabricating apparatus according to a preferred embodiment of the present invention; and

FIGS. 2 to 5 are diagrams for explaining a substrate fabricating apparatus and a substrate fabricating method according to a preferred embodiment of the present invention.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, terms used in the specification, ‘first’, ‘second’, etc. can be used to describe various components, but the components are not to be construed as being limited to the terms. The terms are only used to differentiate one component from other components. Further, when it is determined that the detailed description of the known art related to the present invention may obscure the gist of the present invention, the detailed description thereof will be omitted.

Hereinafter, preferred embodiments of the present invention will be described in detail with reference to the accompanying drawings.

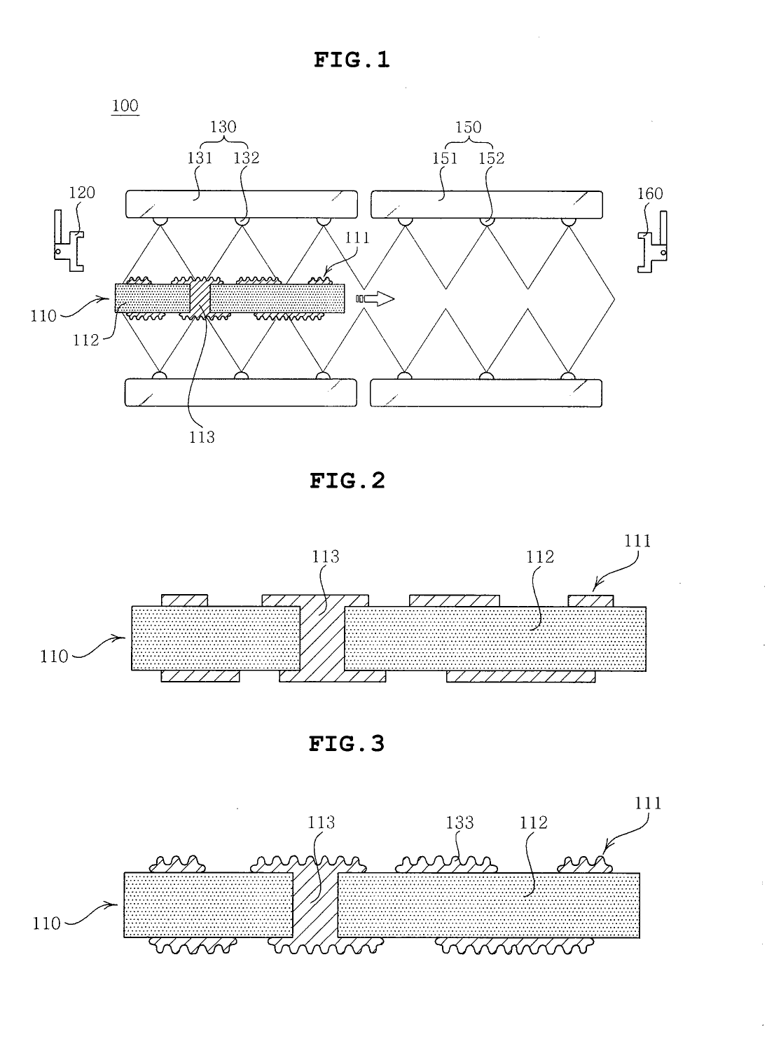

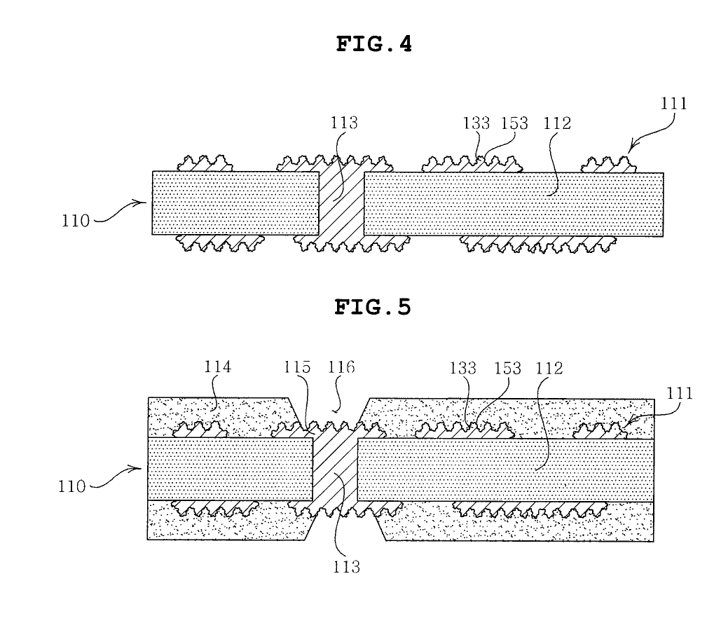

FIG. 1 is a cross-sectional view of a substrate fabricating apparatus 100 according to a preferred embodiment of the present invention and FIGS. 2 to 5 are diagrams for explaining a substrate fabricating apparatus 100 and a substrate fabricating method according to a preferred embodiment of the present invention. Hereinafter, the substrate fabricating apparatus 100 and the substrate fabricating method according to the present embodiment will be described with reference to these drawings.

As shown in FIG. 1, the substrate fabricating apparatus 100 according to the present invention includes a loading part 120 loading a base substrate 110, a first injector 130 forming first type of ruggedness 133 on a circuit layer 111, a second injector 150 forming second type of ruggedness 153 on the circuit layer 111, a moving member (not shown) transporting the base substrate 110, and an unloading part 160 carrying out the base substrate 110.

In this configuration, the preferred embodiment or the present invention describes that the first injector 130 and the second injector 150 are disposed on both surfaces of the base substrate 110, but is not limited thereto. As a result, the first injector 130 and the second injector 150 may be disposed on one surface of the base substrate 110.

First, as shown in FIG. 2, the base substrate 110 where the circuit layer 111 is formed as the outermost layer is loaded on the substrate fabricating apparatus 100 by the loading part 120.

In this case, the loading part 120 may dispose the base substrate 110 up to the first injector 130. For example, the loading part 120 is formed in a jig type including a vacuum suction apparatus or a conveyer belt, etc., thereby making it possible to dispose the base substrate 110 on the first injector 130.

Meanwhile, as shown in FIG. 2, the base substrate 110 of which the outermost layer is formed with the circuit layer 111 may include an insulating layer 112. In addition, the base substrate 110 may include a via 113 connecting the circuit layers 111 formed as the outermost layers on both surfaces thereof to each other. In this configuration, the insulating layer 112 may be, for example, prepreg or epoxy resin, etc., and the circuit layer 111 and the via 113 may be an electric conductive metal, such as, gold, silver, copper, nickel, etc. However, the present invention is not limited thereto and the base substrate 110 may be a printed circuit board including a multi-insulating layer and circuit layer.

Next, as shown in FIG. 3, the first type of ruggedness 133 is formed on the circuit layer 111 of the base substrate 110 by injecting a first etchant from the first injector 130.

In this configuration, the first injector 130 may include a first main body 131 and first nozzles 132. The first nozzle 132 is a member that directly injects the first etchant to the circuit layer 111 and the first main body 131 may provide a path that can connect between the plurality of first nozzles 132 and move the first etchant within the first injector 130. However, the present invention is not limited to the nozzle shape and the case where the first etchant is injected by the first injector 130 and the base substrate 110 is dipped in the first etchant may also be included in the scope of the present invention.

In this case, when the first etchant is injected through the first nozzle 132 of the first injector 130, the first etchant contacts the circuit layer 111 formed as the outermost layer of the base substrate 110, such that the surface of the circuit layer 111 may be etched. In addition, the first type of ruggedness 133 may be formed on the circuit layer 111 while the surface of the circuit layer 111 is etched. In detail, when the first etchant contacts the surface of the circuit layer 111, a portion of metal forming the surface of the smooth circuit layer 111 is ionized by the first etchant to make the surface of the circuit layer 111 rugged, not even, such that the surface of the circuit layer 111 may be formed with the first type of ruggedness 133. In this configuration, the first etchant is preferably different from a second etchant to be described below so that the first type of ruggedness 133 and a second type of ruggedness 153 to be described below have different amplitudes, wavelengths. For example, etchant such as CuCl₂ or FeCl₂ or the like, may be used.

In addition, the first type of ruggedness 133 formed on the surface of the circuit layer 111 by the first etchant may have a “higher ruggedness ” than the second type of ruggedness 153 to be described below. In this case, “high ruggedness” implies that a period is relatively longer than a “low ruggedness” and a distance between the highest point and the lowest point is relatively long. That is, when being described in connection with a frequency, “high ruggedness” implies that it is a low frequency type having a relatively long wavelength and amplitude.

Meanwhile, the first etchant may further be provided with an organic acid. The organic acid is a material assisting to evenly form the first type of ruggedness 133 on the surface of the circuit layer 111 and may be made of, for example, formic acid, phosphoric acid, oxalic acid, or the like.

Next, as shown in FIG. 4, the base substrate 110 moves from the first injector 130 to the second injector 150 and the second type of ruggedness 153 is formed on the circuit layer 111.

In this configuration, the moving member (not shown) is a member moving the base substrate 110 from the first injector 130 to the second injector 150. The moving member (not shown) may be configured of, for example, a motor including a conveyor belt, etc., to consecutively move the base substrate 110.

Meanwhile, when the base substrate 110 is disposed in the second injector 150, the second etchant flowing in the second main body 151 may be injected through the second nozzle 152 and the injected second etchant may contact the circuit layer 111 on which the first type of ruggedness 133 is formed. In addition, when the second etchant contacts the circuit layer 111, a portion of metal forming the circuit layer 111 is ionized by the second etchant such that the second type of ruggedness 153 may be formed in the circuit layer 111. In this case, as the second etchant, a material different from the first etchant, for example, a material such as HCOOH may be used. Further, similar to the first etchant, the second etchant may further include organic acid.

Meanwhile, when the second etchant is injected, the first type of ruggedness 133 provided by the first etchant and the second type of ruggedness 153 provided by the second etchant may coexist on the surface of the circuit layer 111. In this case, the second type of ruggedness 153 is a lower ruggedness type than the first type of ruggedness and may be a high frequency type when being described in connection with a frequency. In this case, the second type of ruggedness 153 is a lower ruggedness type than the first type of ruggedness and may be a high frequency type when being described in connection with a frequency. Therefore, the second type of ruggedness 153 may be a type having a shorter wavelength and smaller amplitude than those of the first type of ruggedness 133.

In this case, the first type of ruggedness 133 and the second type of ruggedness 153 having different wavelengths and amplitudes are formed on the circuit layer 111 by different etchants, such that the surface area of the circuit layer 111 may be relatively widened. That is, since the surface of the circuit layer 111 is more complicated and rugged than the case where a smooth surface or any one type of ruggedness is formed, the specific surface area of the circuit layer 111 may be widened. In addition, various types of ruggedness is formed on the circuit layer 111 to variously implement the specific surface area of the circuit layer 111 since the etchant may be changed and controlled to meet the requirements required for the substrate.

Meanwhile, although the preferred embodiment of the present invention describes that the first type of ruggedness 133 is the high ruggedness and the second type of ruggedness 153 is the low ruggedness, it is possible to implement the case where the first type of ruggedness 133 is low ruggedness and the second type of ruggedness 153 is high ruggedness by mutually changing the materials of the first etchant and the second etchant. In addition, although the preferred embodiment of the present invention describes the substrate fabricating apparatus 100 including the first injector 130 and the second injector 150, the substrate fabricating apparatus 100 in which the injector is configured in three or more may be implemented by further including a third injector (not shown), a fourth injector (not shown), or the like.

Next, the base substrate 110 in which the first type of ruggedness 133 and the second type of ruggedness 153 are formed on the circuit layer 111 as the outermost layer is carried out to the outside of the substrate fabricating apparatus 100 through the unloading part 160.

In this case, the unloading part 160 is configured of a jig or a conveyor belt, etc., similar to the loading part 120, such that the base substrate 110 may be carried out to the outside from the second injector 150.

Next, as shown in FIG. 5, the base substrate 110 in which the first type of ruggedness 133 and the second type of ruggedness 153 are formed on the circuit layer 111 as the outermost layer is formed with a protective layer 114.

In this case, the protective layer 114, which is a member for protecting the circuit layer 111 formed in the base substrate 110 and other components, may be formed of, for example, a solder resist layer. In addition, the protective layer 114 may be further formed with an opening portion 116 exposing a pad part 115 of the circuit layer 111, wherein the opening part 116 may be formed of for example, a photolithography method or a laser method, or the like. In addition, the pad part 115 may be formed with a solder ball (not shown) through the opening part 116.

The substrate fabricating apparatus and the substrate fabricating method according to the present invention inject different etchants by the first injector and the second injector to form different first type of ruggedness and second type of ruggedness on the circuit layer formed as the outermost layer of the base substrate, thereby relatively widening the specific surface area of the circuit layer and solidifying the adhesion between the circuit layer and the protective layer.

In addition, according to the present invention, the injector is formed in plural to inject various etchant, thereby making it possible to variously form the specific surface area of the circuit layer on the substrate according to requirements.

Although the preferred embodiments of the present invention have been disclosed for illustrative purposes, they are for specifically explaining the present invention and thus a substrate fabricating apparatus and a substrate fabricating method according to the present invention are not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A substrate fabricating apparatus, comprising:
a first injector that injects a first etchant to a circuit layer formed as an outermost layer of a base substrate to form first type of ruggedness; and
a second injector that injects a second etchant to the circuit layer formed with the first type of ruggedness to form second type of ruggedness.

2. The substrate fabricating apparatus as set forth in claim 1, further comprising a moving member moving the base substrate from the first injector to the second injector.

3. The substrate fabricating apparatus as set forth in claim 1, further comprising:
a loading part loading the base substrate into the first injector; and
an unloading part carrying out the base substrate from the second injector to the outside.

4. The substrate fabricating apparatus as set forth in claim 1, wherein the first injector and the second injector are disposed on both surfaces of the base substrate.

5. The substrate fabricating apparatus as set forth in claim 1, wherein the first etchant and the second etchant are different from each other.

6. The substrate fabricating apparatus as set forth in claim 1, wherein any one of the first type of ruggedness and the second type of ruggedness has higher ruggedness than the other one.

7. The substrate fabricating apparatus as set forth in claim 1, wherein the first etchant is CuCl₂ or FeCl₂ and the second etchant is HCOOH.

8. The substrate fabricating apparatus as set forth in claim 1, wherein the first etchant, the second etchant, or both the first etchant and the second etchant include organic acid.

9. A substrate fabricating method, comprising:
preparing a base substrate of which the outermost layer is formed with a circuit layer;
forming first type of ruggedness by injecting a first etchant to the circuit layer; and
forming second type of ruggedness by injecting a second etchant to the circuit layer formed with the first type of ruggedness.

10. The substrate fabricating method as set forth in claim 9, wherein the first etchant and the second etchant are injected to the circuit layer formed as the outermost layer on both surfaces of the base substrate.

11. The substrate fabricating method as set forth in claim 9, wherein the first etchant and the second etchant are different from each other.

12. The substrate fabricating method as set forth in claim 9, wherein any one of the first type of ruggedness and the second type of ruggedness has higher ruggedness than the other one.

13. The substrate fabricating method as set forth in claim 9, wherein the first etchant is CuCl₂ or FeCl₂ and the second etchant is HCOOH.

14. The substrate fabricating method as set forth in claim 9, wherein the first etchant, the second etchant, or both the first etchant and the second etchant include organic acid.

15. The substrate fabricating method as set forth in claim 9, further comprising after forming the second type of ruggedness, forming a protective layer on the base substrate formed with the circuit layer.

16. The substrate fabricating method as set forth in claim 15, wherein the protective layer is a solder resist layer.
